(19) United States
(12) Patent Application Publication
(10) Pub. No.: US 2011/0247693 A1
(43) Pub. Date: Oct. 13, 2011

(54) COMPOSITE PHOTOVOLTAIC MATERIALS

(76) Inventor: Richard Brotzman, Naperville, IL (US)

(21) Appl. No.: 12/817,714

(22) Filed: Jun. 17, 2010

Related U.S. Application Data
(60) Provisional application No. 61/219,318, filed on Jun. 22, 2009.

(51) Int. Cl. H01L 31/0256; H01B 1/04

(52) U.S. Cl. 136/263; 252/501.1

(57) ABSTRACT

Compositions, articles, and methods of manufacturing that include a bicontinuous, interpenetrating composite of a semiconducting organic phase; a semiconducting particulate phase; and a plurality of p-n junctions at interfaces between the semiconducting organic phase and the semiconducting particulate phase. The bicontinuous, interpenetrating composite being a new photovoltaic material that can enhance the photovoltaic conversion efficiency and reduce the manufacturing cost of photovoltaic devices.

### REFERENCE TO RELATED APPLICATIONS

This application claims the benefit of U.S. Provisional Application No. 61/219,318 entitled “Composite Photovoltaic Materials” filed Jun. 22, 2009, which is incorporated by reference in its entirety, except where inconsistent with the present application.

### FIELD OF DISCLOSURE

This invention relates to the photo-active materials in photovoltaic devices, specifically solar cells.

### BACKGROUND

Elements of a photovoltaic device (solar cell) are illustrated in FIG. 1. The objective is to generate power by: (1) generating a large short circuit current, I_{sc}, (2) generating a large open-circuit voltage, V_{oc}, and (3) minimizing parasitic power loss mechanisms. I_{sc} depends on 1) generation of radiation-generated carriers, and 2) collection of light-generated carriers. The absorption of incident photons to create electron-hole pairs, as illustrated in FIG. 2, where negative and positive circles represent electron (negative charge carrier) and hole (positive charge carrier), respectively, occurs if the incident photon has energy (Eₚₕ) greater than the band gap (E_{g}). Photons with Eₚₕ<E_{g} are not absorbed and are lost. If a photon has energy above E_{g} the excess energy above E_{g} is lost as heat. Thus, the value of the band gap determines the maximum possible current and generated heat. If the photon absorber is a single material, with a single band gap, available photons are lost and the cell operates at a decreased efficiency.

In current photovoltaic devices, radiation-harvesting materials are employed in planar film architectures. Radiation incident on a planar surface will have a reflected component, which decreases absorption the efficiency—often, antireflective coatings are employed at material interfaces to assuage reflective losses, but reflective losses cannot be eliminated. The use of stacked film architecture (disclosed in U.S. Patent Application 280264475A1) or solar cells stacked in series but electrically insulated (disclosed in U.S. Pat. No. 4,094,704) modestly increases absorption and does not eliminate reflective losses. In addition, the incorporation of antireflective coatings and multilayer device architectures increases device complexity and cost.

The use of organic-inorganic composites in photovoltaic devices is known. Japanese Patent Application 24071682A2 discloses a composite material (titanium oxide mixed with a conducting polymer) used to create a diode which is external to the solar cell and is used to control current conduction. U.S. Pat. No. 4,971,633 discloses a thin film of porous Al₂O₃-styrene-acrylate composite used as a thermally conducting dielectric layer that electrically insulates the solar cells and heat sink. Japanese Patent Application 221 00793A2 discloses a composite material used to form a solar battery. U.S. Pat. No. 6,261,469 discloses three-dimensional periodic arrays of spherical particles processed by one or more extraction and infiltration steps to make an organic-inorganic composite. U.S. Pat. No. 6,710,366 discloses a nanocomposite material, containing a matrix material and a plurality of quantum dots dispersed in the matrix material, with a nonlinear index of refraction and enhanced radiation absorption between 3×10⁻⁵ cm and 2×10⁻⁴ cm. U.S. Patent Application 290071539A1 discloses a nanocomposite, containing amorphous silicon and nanocrystalline silicon, which improves the conversion efficiency of a solar cell.

U.S. Pat. No. 7,341,774 discloses an electronic or opto-electronic device comprising and interpenetrating network of a nanostructured high surface area to volume ratio film material and an organic-inorganic material forming a nanocomposite. This material is formed by depositing the high surface area to volume ratio material onto an electrode substrate, and forming the interpenetrating network by introducing the organic-inorganic network into the void volume of the high surface area to volume ratio material while it is attached to the electrode. The organic-inorganic nanocomposite serves as a filling material surrounding the basic elements of the film.

Konarka disclosed (2008 Nanotechnology Symposium, 20 Nov. 8, Evanston, Ill.) poly-3-hexylthiophene/phenyl C61 Butyric Acid Methyl Ester (P3HT/PCBM) composites as light-harvesting materials in photovoltaic systems. Solar conversion efficiencies of 5%-6.5% were claimed, which is indicative of dispersed composites and not bicontinuous, interpenetrating morphologies.

### SUMMARY OF THE INVENTION

One embodiment of the disclosure is a bicontinuous, interpenetrating composite that includes a semiconducting organic phase; a semiconducting particulate phase; and a plurality of p-n junctions at interfaces between the semiconducting organic phase and the semiconducting particulate phase; wherein the semiconducting organic phase and the semiconducting particulate phase interpenetrate and are bicontinuous.

Another embodiment is a photovoltaic device that includes a conductive front contact; a conductive rear contact; and disposed between the front contact and the rear contact the bicontinuous, interpenetrating composite.

Still another embodiment is a method of manufacturing the bicontinuous, interpenetrating composite that includes admixing an organic polymer, a first plurality of particles, and a second plurality of particles; wherein the first plurality of particles has an amount of surface treatment that is greater than the second plurality of particles.

### BRIEF DESCRIPTION OF THE DRAWINGS

FIG. 1 is an exemplary depiction of the elements of a solar cell.

FIG. 2 is an exemplary depiction of the absorption of incident photons to create electron-hole pairs.

FIG. 3 illustrates a solar cell.

### DETAILED DESCRIPTION

The present invention makes use of an organic-particulate composite with a bicontinuous, interpenetrating morphology (i.e., a bicontinuous, interpenetrating composite). The composite acts as the radiation-harvesting element in a photovoltaic device. The bicontinuous, interpenetrating composite contains two continuous bulk phases: an organic phase and a particulate phase. In one embodiment, both phases can absorb incident radiation, and can generate radiation-generated charge carriers. The bicontinuous, interpenetrating composite further includes, at the interface between the two phases, a p-n junction, preventing recombination of radiation-generated charge carriers and allowing for collection of the radiation-generated charge carriers. In one embodiment, the presence of the electric field at the p-n junction interface spatially separates electrons and positive charge carriers.

In one embodiment, the bicontinuous, interpenetrating composite is a three-dimensional bulk material containing the two phases: the organic phase and the particulate phase. In this embodiment, the organic phase is either an n-type or p-type semiconducting polymer. The particulate phase is an assembly of particles, or composite particles, containing semiconductor and/or metallic materials with complementary electrical properties to the organic phase (i.e., if the organic phase is an n-type semiconducting polymer then the particulate phase is a p-type material; alternatively if the organic phase is p-type then the particulate phase is n-type). One method of manufacturing the bicontinuous, interpenetrating composite is by surface treating the particles of the particulate phase, and admixing the organic polymer and surface treated particles to form the bicontinuous, interpenetrating morphology.

In one embodiment, the particulate phase is a continuous or semi-continuous, network of particles containing an inorganic semiconductor and/or metallic material. Examples include particles of semiconducting polymers (described in more detail below), inorganic materials, semiconductor materials, and metallic materials. Examples of inorganic materials include alumina, zirconium oxide, silicon oxide, and mixtures thereof. Examples of inorganic semiconductors include silicon, germanium, and mixtures thereof; titanium dioxide, zinc oxide, indium-tin oxide, antimony-tin oxide, and mixtures thereof; 2-6 semiconductors, which are compounds of at least one divalent metal (zinc, cadmium, mercury and lead) and at least one divalent non-metal (oxygen, sulfur, selenium, and tellurium) such as zinc oxide, cadmium selenide, cadmium sulfide, mercury selenide, and mixtures thereof; 3-5 semiconductors, which are compounds of at least one trivalent metal (aluminum, gallium, indium, and thallium) with at least one trivalent non-metal (nitrogen, phosphorous, arsenic, and antimony) such as gallium arsenide, indium phosphide, and mixtures thereof; and group 4 semiconductors including hydrogen terminated silicon, germanium, and alpha-tin, and combinations thereof.

Examples of metallic materials include gold, silver, platinum particles, and mixtures thereof; metallic clusters such as nickel, palladium, gold, copper, and mixtures thereof; and sub-oxidized metal oxides such as Ti-rich titanium oxide, Zn-rich zinc oxide, Zr-rich zirconium oxide, and mixtures thereof.

Types of particulate semiconductors materials are yielded by variations including: (1) single or mixed elemental compositions; including alloys, core/shell structures, doped particles, and combinations thereof; (2) single or mixed shapes and sizes, and combinations thereof; and (3) single form of crystallinity or a range or mixture of crystallinity, and combinations thereof.

Preferably, the particulate phase contains a plurality of particles with different band gaps. The band gap of semiconductors may be modified by inclusion of small amounts of an element, which will replace one of the existing elements within the structure, without changing the crystal structure. Examples include replacing a small amount of aluminum in aluminum oxide with indium, or small amounts of oxygen with nitrogen or sulfur in titanium oxides. Compounds of two semiconductors with similar structures may also be used to change the band gap, such as compounds of zinc sulfide and cadmium selenide, or aluminum oxide and indium oxide. Another way to modify the band gap is to coat the semiconductor with another material, such as a metal, for example aluminum, copper, silver or gold; the band of the semiconductor and the metal will move towards each other at the interface, affecting the band gaps at the interface. Another way to modify the band gap is by blending doped and un-doped group 4 semiconductor particles. For example, p-type dopants for silicon include boron, aluminum, and gallium; and n-type dopants for silicon include phosphorus, arsenic, and antimony.

Examples of particles that may be used as the particulate phase include semiconductor nanocrystals. Semiconductor nanocrystals have been known for many years, and the preparation of these material is described, for example, in C. B. Murray, C. R. Kagan, and M. G. Bawendi, Annu. Rev. Mater. Sci., 2000, 30, 545; C. B. Murray, D. J. Norris, and M. G. Bawendi, J. Am. Chem. Soc., 1993, 115, 8706; and J. E. Bowen Katari, V. L. Colvin, and A. P. Alivisatos, J. Phys. Chem., 1994, 98, 4109. A striking feature of semiconductor nanocrystals is that their band gap may be controlled by their size. Semiconductor nanocrystals may be formed as mixtures with a core-shell structure; a first composition will form the core (for example, CdSe), and this core will be surrounded by a shell of a second composition (for example ZnS). The preparation of these materials is described in M. A. Hines and P. Guyot-Sionnest, J. Phys. Chem., 1996, 100, 468. Examples include core/shell pairs CdSe/ZnS, CdSe/CdS, InAs/CdSe, InAs/InP, ZnS/CdSe, CdS/CdSe, CdSe/InAs and InP/As.

Semiconductor nanocrystals may be formed with capping groups on their surfaces. Capping groups are moieties that are attached to the surface of the semiconductor nanocrystals, and are included during the synthesis of colloidal nanocrystals. In the form of colloids, they are easily manipulated, and may be mixed with a solvent including non-polar and polar organic solvents, such as alkanes (for example, hexane and pentane), ethers (diethyl ether and tetrahydrofuran), benzene, toluene, styrene, dichloromethane, styrene, xylene, dimethyl formamide, carbonates (propylene carbonate), dimethyl sulfoxide, and mixtures thereof. The capping groups are readily exchangeable, as described in Bruchez Jr., M., Moronne, M., Gin, P., Weiss, S. & Alivisatos, A. P. Science, 1998, 281, 2013-2016; and Chan, W. C. W. & Nie, S. Science, 1998, 281, 2016-2018.

The particulate phase preferably contains a plurality of particles from 1 nm to 5 microns in diameter. For example, the particle diameter may be from 1 nm to 500 nm, or the particle diameter may be from 1 nm to 100 nm. When the plurality of particles in the particulate phase has a diameter of less than 100 nm, and the radiation-harvesting composite is thin, internal shadowing may be substantially zero, which can enhance efficiency.

The particulates self-organize, or self-assemble, into a connected bulk phase. Fabrication of the particulate phase using self-organization relies on the selection of an amount of surface treatment for the particles that exert attracting and repelling forces on one another and the organic phase. An “attracting” or “repelling” force is understood to mean a surface force that isolates the two phases into a bicontinuous, interpenetrating morphology. Self-assembly of the particles is controlled by dispersion forces, which are quantified by the Hamaker constant, the description of the Hamaker constant as described in U.S. Pat. No. 7,387,851 is incorporated herein by reference in its entirety. The un-treated portion of the surface of the particles will be attractive to one another and the treated portion of the surface of the particles will be attracted to the organic phase yielding a controlled aggregation of the inorganic particles and a continuous, or semi-continuous, network of particles.

In another embodiment, the particles can be rendered more compatible with the organic phase by surface treatment. Examples of surface treatment agents include phenylene agents: for example, triphenylethoxysilane, diphenyldiethoxysilane, phenyltriethoxysilane, triphenyltinhydride, triphenyltinhydroxide, tetraphenyltin, hexaphenylditin, and mixtures thereof. These surface treatment agents can facilitate the formation of a p-n junction and, structurally, the p-n junction includes the reaction product of the surface treatment agent and the plurality of particles of the particulate phase. For example, the p-n junction can include a phenylene that is disposed to the particulate phase (i.e., the reaction product of the phenylene agent with the plurality of particles of the particulate phase, or other phenylene agents to effectively encapsulate particles of the particulate phase). The surface-treatment agent may separate the organic and particulate phases, by at least molecular dimensions (approximately 0.1 nm to 20 nm). Preferably, the surface treatment inhibits hole (cation) transport, and preferably, the surface treatment introduces an electron-rich material, such as a material with electrons, which are π-conjugated, onto the surface of the particles.

The amount of surface treatment of the particles, that is the average percentage of surface treatment over a plurality of particles, can be in a range of about 20% to about 80%. The amount of surface treatment of the particles can be 20%, 25%, 30%, 35%, 40%, 45%, 50%, 55%, 60%, 65%, 70% or 75% of the surface. At least a portion of the particles has only a portion of their surfaces treated. Preferably, at least some of the particles have untreated surfaces. By forming a mixture of particles with different amounts of surface treatment, a continuous phase will self-organize. Preferably, a first plurality of particles has an amount of surface treatment that is greater than a second plurality of particles. Preferably, the first plurality of particles has an amount of surface treatment of 60% and the second plurality of particles has an amount of surface treatment of 30%.

In one embodiment, the bicontinuous, interpenetrating composite is manufactured by forming an admixture of a liquid monomer, a solvent, and colloidal semiconductor nanocrystals, and then polymerizing the monomer.

The organic phase contains organic semiconductors, variously called π-conjugated polymers, conducting polymers, or synthetic metals, which are inherently semiconductive due to π-conjugation between carbon atoms along the polymer backbone. Their structure contains a one-dimensional organic backbone, which enables electrical conduction following n− type or p+ type doping.

Well-studied classes of organic conductive polymers include poly(acetylene)s, poly(pyrrole)s, poly(thiophene)s, polyanilines, polythiophenes, poly(p-phenylene sulfide), poly(para-phenylene vinylene)s (PPV) and PPV derivatives, poly(3-alkylthiophenes), polyindole, polypyrene, polycarbazole, polyazulene, polyazepine, poly(fluorene)s, and polynaphthalene. Other examples include polyaniline, polyaniline derivatives, polythiophene, polythiophene derivatives, polypyrrole, polypyrrole derivatives, polythianaphthene, polythianaphthane derivatives, polyparaphenylene, polyparaphenylene derivatives, polyacetylene, polyacetylene derivatives, polydiacethylene, polydiacetylene derivatives, polyparaphenylenevinylene, polyparaphenylenevinylene derivatives, polynaphthalene, and polynaphthalene derivatives, polyisothianaphthene, polyheteroarylenvinylene, in which the heteroarylene group can be e.g. thiophene, furan or pyrrol, polyphenylene-sulphide, polyperinaphthalene, polyphthalocyanine etc., and their derivatives, copolymers thereof and mixtures thereof. As used herein, the term derivatives means the polymer is made from monomers substituted with side chains or groups.

The method for polymerizing the conductive polymers can include electrolytic oxidation polymerization, chemical oxidation polymerization, and catalytic polymerization. The polymer obtained by the polymerization of the liquid monomer can be neutral and/or nonconductive until doped. Therefore, a neutral and/or nonconductive polymer is subjected to p-doping or n-doping to form the conductive polymer. In another embodiment, the semiconductor polymer may be doped chemically, or electrochemically. The dopants are not particularly limited; examples include a substance capable of accepting an electron pair, such as a Lewis acid, hydrochloric acid, sulfuric acid, organic sulfonic acid derivatives such as parasulfonic acid, polystyrenesulfonic acid, alkylbenzenesulfonic acid, camphorsulfonic acid, alkylsulfonic acid, sulfosalycilic acid, other sulfonic acids, ferric chloride, copper chloride, iron sulfate, or mixtures thereof.

The organic-particulate composite may be processed as a liquid, which increases manufacturing speed and reduces manufacturing costs. The light harvesting material may be processed using known solution processing methods, for example spray, curtain coating, ink-jet, and other similar methods, using conventional film processing equipment.

The composite is preferably formed by first forming a liquid containing the particulate phase and the polymer dissolved in solution, or monomers of the polymer dissolved in solution. Any solvent may be used in which the polymer or its monomers dissolves and the particles dispersed. Examples of solvents include water, alcohols such as methanol, ethanol, propanol, butanols, glycerin, acetonitile, tetrahydrofuran, dimethyl formamide, N-methyl formamide, glycols such as ethylene glycol, propylene glycol, carbonates such as propylene carbonate, dimethyl sulfoxide, and mixtures thereof. When the polymer is formed in situ by polymerizing monomers or pre-polymers, then any solvent may be used in which the remaining components may be dissolved or dispersed. Examples include the solvents noted above, as well as organic solvents. If the polymer is formed in situ from monomers, then the monomer itself may be used in place of the solvent or with a small amount of solvent to control viscosity, as long as the remaining components may be dissolved or dispersed.

Processing aids may also be used. Examples of processing aids include carbon black, colloidal metals such as colloidal gold, the surface-treatment agents, and graphene. These conductive materials will naturally migrate to the interfaces and help prevent the formation of defects or structures which could trap electron and/or holes, allowing the continuous networks to conduct away the electrons and holes as they form.

In another embodiment, the bicontinuous, interpenetrating composite is an active layer in a photovoltaic device. The photovoltaic device includes a conductive front contact and a conductive rear contact with the bicontinuous, interpenetrating composite disposed there between. To facilitate the migration of photoelectrical charges in the bicontinuous, interpenetrating composite, the bicontinuous, interpenetrating composite can be disposed between a first layer of the particles and a second layer of the organic conductive polymer, where either the conductive front or the rear contact contacts the first layer and the other conductive contact contacts the second layer.

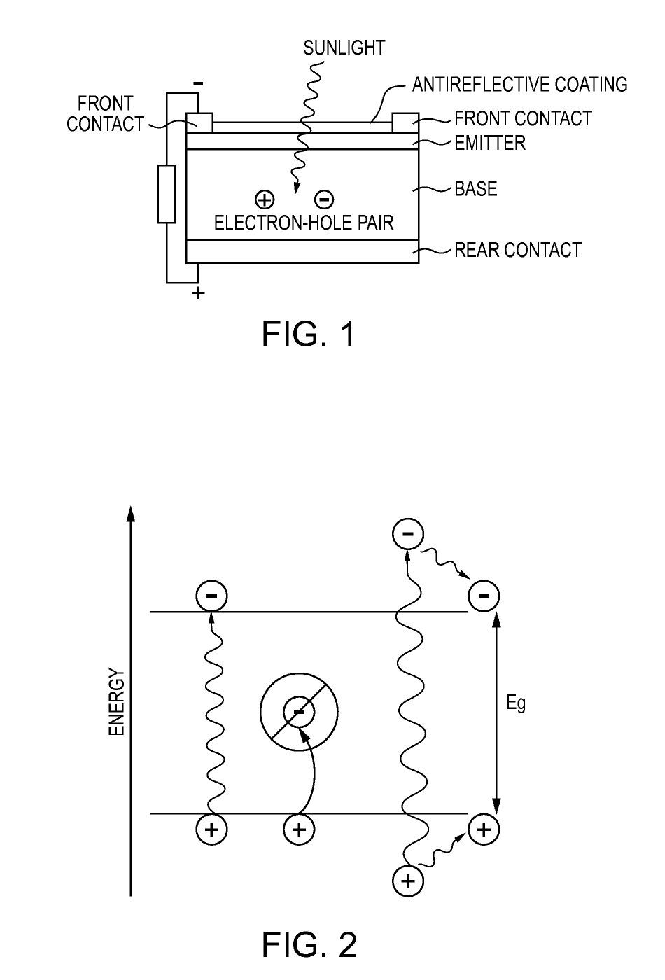

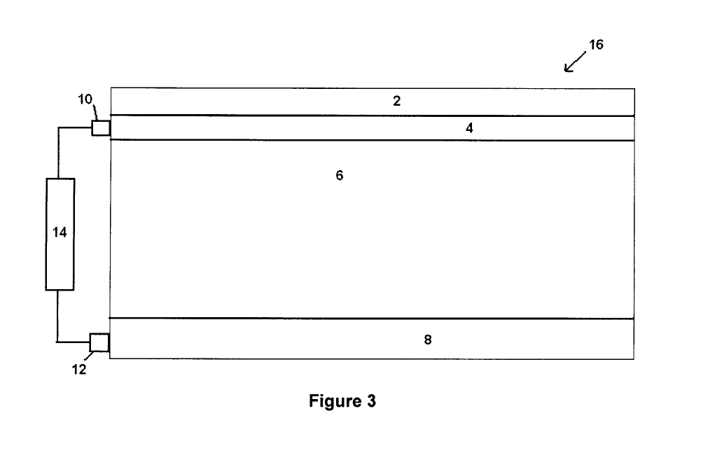

FIGS. 1 and 3 illustrate a photovoltaic device. As illustrated, a photovoltaic device 16 can include an optional transparent plastic base 2; a layer of the particles, preferably without surface treatment 4 on the base; an absorber layer that includes the bicontinuous, interpenetrating composite 6, on the layer of particles; and a layer of the organic phase 8, on the composite. When exposed to light, the composite may form radiation-generated charge carriers, which are separate and conducted separately by either the organic phase or the particulate phase, to the layer of the organic phase or the layer of particles, respectively. The charge carriers then travel via conductive contacts (a front contact) 10, (a rear contact) 12, to a device 14. The device may measure current or voltage, or may store or use the electricity to carry out useful work. Preferably, the particles, if doped, have complementary electrical properties of the organic phase. Other elements typically found in photovoltaic device may optionally be included.

The present invention may increase photovoltaic efficiency by several mechanisms. Incident radiation may be absorbed by both phases of the composite, with the particulate phase containing a number of chemistries and particles sizes. Each component of the composite may have a specific band gap, but the assembled composite has a distribution of band gaps that may be tailored to fully absorb or nearly fully absorb all incident radiation. In effect, a triple-junction (or higher) monolayer solar cell may be made. Net photoelectric conversion efficiencies may be substantially greater than conventional planar multi-junction devices; whereas CIGS or CdTe photoelectric conversion efficiencies are approximately 10% to 12%. In one embodiment, the present invention has photoelectric conversion efficiencies from 25% to 35%.

Using zinc oxide as at least one component of the particulate phase may increase absorption of UV radiation. Not only may the radiation-absorption spectrum be shifted to higher frequencies, but by absorbing UVA radiation in the particulate phase potential damage to the organic phase may be assuaged and device lifetimes may be greater than corresponding devices containing organic light-absorbing materials.

The interface within the composite material may have a large 3-dimensional surface area to volume ratio and operate as an internal scattering element. Incident radiation may be scattered into the composite by forward reflection from the organic-particulate interfaces in the composite—effectively increasing the path length of the material and possibly providing for a greater effective radiation absorption cross-section.

The bicontinuous, interpenetrating morphology may enable three-dimensional connectivity—mechanically and electrically. Electrons may flow from one phase and positive charge carriers may flow from the other phase. The three-dimensional connectivity may enable electrical connections to device edges and may prevent shadowing effects caused by surface electrodes, which decrease the efficiency of current devices.

The interface within the composite material has a large 3-dimensional surface area to volume ratio and may operate as a p-n junction. The spatial distance between two interfaces within the bicontinuous, interpenetrating material is small, on the order of 1 nm to 1 micron, and minority charge carriers will have short diffusion distances to the interface, possibly decreasing the probability of electron-hole recombination events, and possibly increasing photovoltaic efficiency.

### EXAMPLES

### Example 1

A composite formed using p-type semiconducting polymer: A p-type organic semiconductor, poly(3,4-ethylenedioxythiophene) (PEDOT) is dissolved in a suitable solvent.

Antimony tin oxide (ATO) particles, 60-nm in diameter, are surface treated with phenyltriethoxysilane (PTES) to make two types of material. The first is 30% surface treated (ATO-PTES-30) and the second is 60% surface treated (ATO-PTES-60). Two similar types of tin oxide (TO) are made -TO-PTES-30 and TO-PTES-60.

PEDOT is mixed with particulate phase to form 4 mixtures. The PEDOT mixtures were coated on a plastic substrate using the solvent-based technique doctor-blading (drop casting, spin-coating, inkjet printing, screen printing, spraying, and other solvent-based coating techniques would have been equally acceptable).

Bicontinuous, interpenetrating morphologies were formed when PEDOT/total particulate ratios varied from 40% to 60%. The ratio of −60/−40 particulate ratio is 1, but this ratio may be varied to yield specific device properties. The ratio of ATO/TO is controlled to yield the desired phase electrical conductivity.

### Example 2

A composite formed using n-type semiconducting polymer: A n-type organic semiconductor, Poly(pyridine-2,5-diyl) (PPD) is dissolved in a suitable solvent.

Aluminum oxide (AO) particles, 60-nm in diameter, are surface treated with phenyltriethoxysilane (PTES) to make two types of material. The first is 30% surface treated (AO-PTES-30) and the second is 60% surface treated (AO-PTES-60).

PPD is mixed with particulate phase to form 2 mixtures. The PPD mixtures were coated on a plastic substrate using the solvent-based technique doctor-blading (drop casting, spin-coating, inkjet printing, screen printing, spraying, and other solvent-based coating techniques would have been equally acceptable).

Bicontinuous, interpenetrating morphologies were formed when PPD/total particulate ratios varied from 40% to 60%. The ratio of −60/−40 particulate ratio is 1, but this ratio may be varied to yield specific device properties.

1.-10. (canceled)

11. A bicontinuous, interpenetrating composite comprising:
a semiconducting organic phase;
a semiconducting particulate phase; and
a plurality of p-n junctions at interfaces between the semiconducting organic phase and the semiconducting particulate phase;
wherein the semiconducting organic phase and the semiconducting particulate phase interpenetrate and are bicontinuous.

12. The bicontinuous, interpenetrating composite of claim 11, wherein the semiconducting organic phase is either a p-type organic semiconductor or a n-type organic semiconductor.

13. The bicontinuous, interpenetrating composite of claim 12, wherein the semiconducting organic phase is a p-type organic semiconductor and the semiconducting particulate phase is a n-type particulate semiconductor.

14. The bicontinuous, interpenetrating composite of claim 12, wherein the semiconducting organic phase is a n-type organic semiconductor and the semiconducting particulate phase is a p-type particulate semiconductor.

15. The bicontinuous, interpenetrating composite of claim 11, wherein the p-n junctions include a phenylene bound to the particulate phase.

16. The bicontinuous, interpenetrating composite of claim 11 further comprising a processing aid.

17. The bicontinuous, interpenetrating composite of claim 11, wherein the semiconducting particulate phase comprises a plurality of particles that have different band gaps.

18. The bicontinuous, interpenetrating composite of claim 17, wherein the semiconducting particulate phase comprises a plurality of particles that have a diameter of from 1 nm to 500 nm, or from 1 nm to 100 nm.

19. The bicontinuous, interpenetrating composite of claim 11, wherein the semiconducting particulate phase comprises a first plurality of particles and a second plurality of particles; and wherein the first plurality of particles has an amount of surface treatment that is greater than the second plurality of particles.

20. A photovoltaic device comprising:
a conductive front contact;
a conductive rear contact; and disposed between the front contact and the rear contact;
a bicontinuous, interpenetrating composite that comprises a semiconducting organic phase, a semiconducting particulate phase, and a plurality of p-n junctions at interfaces between the semiconducting organic phase and the semiconducting particulate phase, wherein the semiconducting organic phase and the semiconducting particulate phase interpenetrate and are bicontinuous.

21. The photovoltaic device of claim 20 further comprising
a n-type layer and a p-type layer,
wherein the bicontinuous, interpenetrating composite is disposed between the n-type layer and the p-type layer.

22. A method of manufacturing a bicontinuous, interpenetrating composite that comprises a semiconducting organic phase, a semiconducting particulate phase, and a plurality of p-n junctions at interfaces between the semiconducting organic phase and the semiconducting particulate phase, the method comprising:
admixing an organic polymer, a first plurality of particles, and a second plurality of particles;
wherein the first plurality of particles has an amount of surface treatment that is greater than an amount of surface treatment on the second plurality of particles.

23. The method of claim 22, wherein admixing the organic polymer comprises admixing the first plurality of particles and the second plurality of particles with a liquid monomer; and then polymerizing the monomer.

24. The method of claim 23, wherein admixing the organic polymer comprises admixing the first plurality of particles and the second plurality of particles with a liquid monomer, a solvent, and a processing aid; and then polymerizing the monomer.

25. The method of claim 22 further comprising casting the admixture onto a plastic substrate.
